(19) United States
(12) Patent Application Publication
(10) Pub. No.: US 2006/0086941 A1
(43) Pub. Date: Apr. 27, 2006

(54) Superluminescent diode including active layer formed of various sized quantum dots and method of manufacturing the same

(76) Inventors: Il Ki Han, Seoul (KR); Jung Il Lee, Seoul (KR); Young Chai Yoo, Seoul (KR)

Correspondence Address: JONES DAY, 222 EAST 41ST ST, NEW YORK, NY, 10017, US

(21) Appl. No.: 11/262,341

(22) Filed: Oct. 27, 2005

(30) Foreign Application Priority Data
Oct. 27, 2004 (KR) 10-2004-0086139

(51) Int. Cl. H01L 33/00

(52) U.S. Cl. 257/79; 257/94

(57) ABSTRACT

The present invention provides a superluminescent diode, which has a wide wavelength bandwidth and a high optical power, and a method of manufacturing the same. The superluminescent diode includes an active layer having a chirped quantum dot (CQD) structure formed over the substrate, wherein the active layer emits lights of at least two different wavelengths.

### FIELD OF THE INVENTION

The present invention generally relates to superluminescent diodes (SLD), and more particularly to a superluminescent diode including an active layer formed of various sized quantum dots and a method of manufacturing the same.

### BACKGROUND OF THE INVENTION

A semiconductor light emitting device includes a p-n junction and emits energy in the form of light corresponding to an energy gap between an electron and a hole which are recombined when current is applied to the p-n junction. A light emitting diode (LED) and a laser diode are typical examples of the semiconductor light emitting device.

The LED includes an active layer having a low energy-band gap, which is formed between semiconductor layers having high energy-band gaps. Light is spontaneously emitted from the active layer. The LED outputs light having wide bandwidth and low optical power of several mW. Generally, the optical power of the LED increases in proportion to the intensity of current applied to the active layer. However, only a small part of the electric energy is transformed to the optical energy. A significant part of the electric energy is not transformed to the optical energy but accumulated as a thermal energy in the LED. Accordingly, there is a problem in that high optical power cannot be generated with currents above a certain extent due to the thermal energy accumulated in the LED.

A laser diode generates light by stimulated emission in an active layer. Once an oscillation occurs, which increases coherence of the lights, all the lights emitted from the active layer are amplified in the same direction and phase. As such, the laser diode has much higher optical power than the LED. However, resonance mode is made in a resonator of the laser diode simultaneously with the occurrence of the oscillation and lights are selectively oscillated at few wavelengths with large gain. Thus, unlike the LED, the wavelength bandwidth of the laser diode is narrow and ranges from several kHz to hundreds of MHz at most.

A light emitting device, which has wide wavelength bandwidth and high optical power, is called a superluminecent diode. The superluminecent diode is a semiconductor diode that has the properties of wide wavelength bandwidth of the LED and high optical power of the laser diode. Therefore, the superluminecent diode can be obtained through increasing the optical power of LED or widening the wavelength bandwidth of the laser diode. Particularly, the superluminecent diode is ‘a laser diode without a resonance mode’.

The structures of an active layer and an electrode of the superluminescent diode are different from those of the conventional laser diode. Specifically, although a multi-layer quantum well structure, which has a plurality of quantum wells overlapped each other, is commonly adopted in the laser diode and the superluminescent diode to obtain enough optical gain, each quantum well of the laser diode should have the same thickness and composition, if possible. However, each quantum well of the superluminescent diode has different thickness and composition. The multi-layer quantum well composed of a plurality of quantum wells having different thickness or composition is known as chirped quantum well (CQW). With the CQW, energy levels created in each quantum well can be changed. Thus, the effect of wavelength bandwidth increase can be acquired (see Jpn. J. Appl. Phys. Vol. 38, 5121, 1999).

Referring to FIGS. 1A and 1B, a structure of the quantum well incorporated into a conventional superluminescent diode will be explained. As shown in FIGS. 1A, the superluminescent diode adopts the CQW structure composed of a plurality of quantum wells having different thickness and composition. In the CQW structure, the energy levels of electrons and holes in each quantum well are different from one another. Thus, different wavelengths λ₁, λ₂ and λ₃, which correspond to the differences of energy level of the electrons and holes (i.e., Ee1-h1, Ee2-h2, Ee3-h3), are emitted as shown in FIG. 1B. Therefore, it is possible to get wide wavelength bandwidth.

FIG. 2 is a perspective view showing the structure of an electrode in a conventional edge-emitting laser diode. FIGS. 3A to 3C are perspective views showing representative structures of electrodes in conventional superluminescent diode. As shown in FIG. 2, an electrode 1 of the conventional edge-emitting laser diode is parallel to a central axis that is vertical to two mirrors 2 and 3 at both sides of an active medium. The two mirrors 2 and 3 can be formed through cleaving two planes of a semiconductor substrate in parallel. As shown in FIGS. 3A to 3C, an electrode 4 of the superluminescent diode slants against the central axis of the active medium by a predetermined slope, in contrast to the electrode 1 of the conventional edge-emitting laser diode. The slope is determined in consideration of the wavelength of lights to be emitted from the superluminescent diode. For example, if it is required to get a light having 1.5 μm wavelength from the superluminescent diode, the electrode should be slanted against the central axis of the active medium by 7°. The electrode of the superluminescent diode is slanted so that light, which has acquired enough optical gain while passing through the active layer, can be prevented from being reflected to the active medium. If the electrode is perpendicular to two mirrored-sides of the active medium, the Fabry-Perot mode is formed through the reflection to the active medium. Eventually, a laser diode is made instead of the superluminescent diode.

Of course, the superluminescent diode can be manufactured with the electrode perpendicular to the mirrored-side of the active medium. However, in such a case, at least one side of the two mirrored-sides of the active medium should be coated with anti-reflection (AR) material having reflection rate of about 10⁻⁵ in order to prevent the reflection through the mirrored-side of the active medium. However, the AR coating process capable of guaranteeing the reflection rate of 10⁻⁵ needs very precise and strict work. Thus, reproducibility, mass production and price competitiveness cannot be anticipated in the manufacturing process of superluminescent diode having the electrode perpendicular to the mirrored-sides of the active medium.

The electrode of the conventional laser diode has a shape of stripe or line. However, the electrode of superluminescent diode has various shapes such as a tapered shape, a tapered line shape, a ‘J’ shape. Thus, the resonance mode does not occur.

The resonator is an essential component in the laser diode but not in the superluminescent diode. The resonator of the laser diode has two parallel mirrored-sides formed by cleaving. In the superluminescent diode, to prevent the occurrence of the resonance mode, two mirrored-sides formed on both ends of cleaving planes of semiconductor substrate are not parallel to each other. For example, a first mirrored-side of the superluminescent diode is formed through cleaving the semiconductor layer. However, a second mirrored-side is formed by etching the semiconductor layer so that the second mirrored-side is sloped by a predetermined degree to the first mirrored-side.

There had been various attempts to embody the superluminescent diode. For example, multi-layer quantum well technology and multi-layer quantum dot technology are used to form the active layer. Also, the electrode is formed in various shapes, such as the tapered shape, the J-shape and an angled stripe shape, etc., as shown in FIGS. 3A to 3C. However, with conventional methods, it is difficult to get wide wavelength bandwidth and high optical power continuously.

### SUMMARY OF THE INVENTION

The present invention provides a superluminescent diode with wide wavelength bandwidth and high optical power, as well as a method of manufacturing the same.

The present invention also provides the superluminescent diode having an active layer formed of various sized quantum dots and a method of manufacturing the same.

### BRIEF DESCRIPTION OF THE DRAWINGS

FIG. 1A is an energy diagram showing a structure of quantum well of a conventional superluminecent diode.

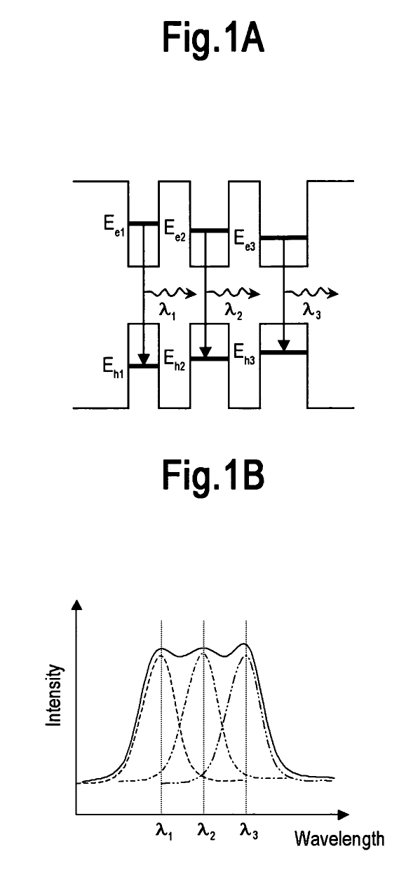

FIG. 1B is a graph showing distribution of wavelengths of lights emitted by a recombination of electrons and holes in the quantum well structure shown in FIG. 1A.

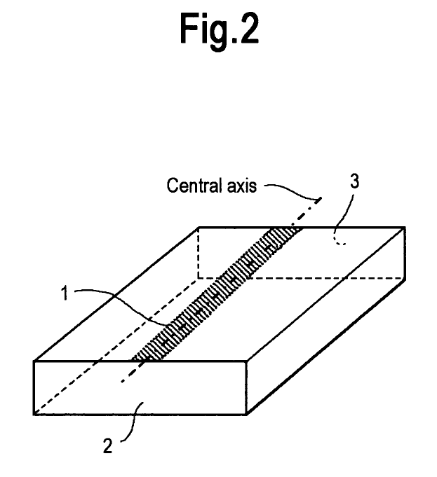

FIG. 2 is a perspective view showing the structure of an electrode in a conventional edge-emitting laser diode.

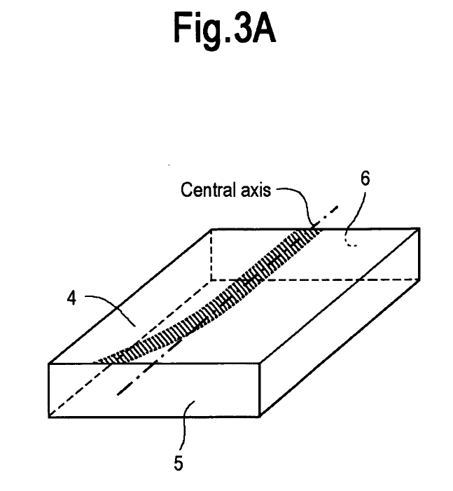

FIGS. 3A to 3C are perspective views showing several representative structures of electrodes in the conventional superluminescent diode.

FIG. 4 is a schematic diagram showing an active layer formed of chirped quantum dot structure, which has two different energy bands in accordance with a first embodiment of the present invention.

FIG. 5 is a schematic diagram showing an active layer formed of another CQD structure, which has at least three different energy bands in accordance with a second embodiment of the present invention.

FIG. 6 is a cross-sectional view of a schematic epi-structure of the superluminescent diode of FIG. 5.

FIG. 7 is a graph showing PL characteristics of the CQD structures illustrated in FIGS. 4 and 5.

FIG. 8A is a top view showing a schematic structure of a superluminescent diode having a J-shaped electrode in accordance with the first and second embodiments of the present invention.

FIG. 8B is a perspective view showing the schematic structure of the superluminescent diode in FIG. 8A.

FIG. 9 is a graph showing EL characteristics of the superluminescent diode formed with the active layer having the CQD structure shown in FIG. 4 and the J-shaped electrode shown in FIGS. 8A and 8B.

FIG. 10 is a graph showing EL characteristics of the superluminescent diode formed with the active layer having the CQD structure shown in FIG. 5 and having the J-shaped electrode shown in FIGS. 8A and 8B.

FIG. 11 is a graph showing current-optical power characteristics of the superluminescent diode formed with the CQD structure.

### DETAILED DESCRIPTION OF THE PRESENT INVENTION

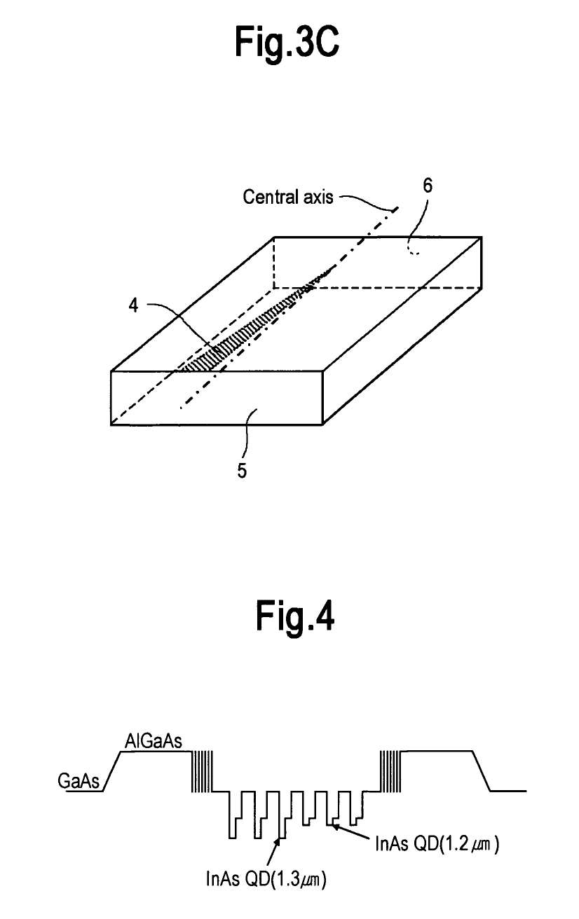

Referring to FIGS. 4 to 11, preferred embodiments of the present invention will now be described below.

FIG. 4 is a schematic diagram showing an active layer formed of a multi-layer quantum dot structure, which has two different energy bands according to the first embodiment of the present invention. The active layer has a chirped quantum dot (CQD) structure composed of three quantum dot layers and other three quantum dot layers emitting lights of 1.3 μm and 1.2 μm wavelength, respectively, when electrons and holes are recombined.

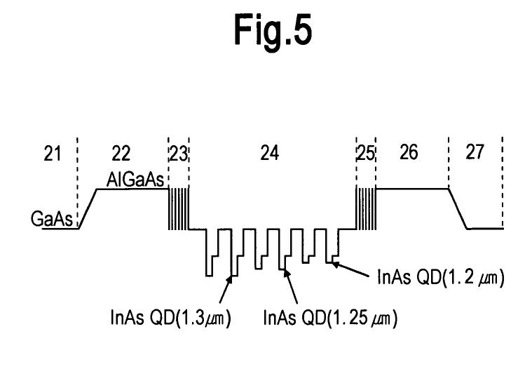

FIG. 5 is a schematic diagram showing an active layer formed with the CQD structure, which has at least three different energy bands in accordance with the second embodiment of the present invention. The CQD structure includes two quantum dot layers, which emit light of 1.25 μm wavelength, between two quantum dot layers emitting lights of 1.3 μm wavelength and other two quantum layers emitting light of 1.2 μm wavelength. In FIG. 5, ‘21’ represents a GaAs substrate, ‘22’ and ‘26’ represent AlGaAs cladding layers, ‘23’ and ‘25’ represent superlattice layers, ‘24’ represents an active layer, and ‘27’ represents an ohmic layer. The active layer 24 has the same energy band as the conventional active layer formed with a chirped quantum well (CQW) structure, which includes a plurality of quantum wells having different thickness and composition. Therefore, lights having different wavelengths, 1.2 μm, 1.25 μm and 1.3 μm, which correspond to the energy level differences between the electrons and holes in the active layer, are emitted. Thus, the wavelength bandwidth becomes wide.

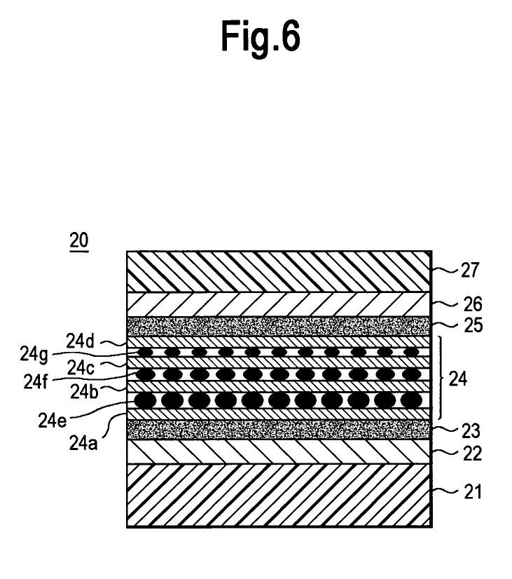

FIG. 6 shows a schematic epi-structure 20 of the superluminescent diode in accordance with the second embodiment of the invention. The superluminescent diode includes an n+-type substrate 21, an n-type cladding layer 22, a first superlattice layer 23, an active layer 24 having the CQD structure, a second superlattice layer 25, a p-type cladding layer 26 and a p+-type ohmic layer. The n+-type substrate 21 can be formed of a GaAs compound semiconductor substrate. The n-type cladding layer 22 can be formed through growing a silicon doped AlGaAs compound semiconductor on the n+-type substrate 21. The first superlattice layer 23 can be obtained by alternately growing a plurality of AlGaAs layers and GaAs layers, which have the same lattices constant, on the n-type cladding layer 22. The active layer 24 having the CQD structure can be formed through growing the quantum dots according to the commonly known Stranski-Krastinov (S-K) mode. Namely, the active layer 24 can be formed by a self-assembled quantum dot growth induced by the lattices mismatch of the GaAs and InAs layers.

In accordance with one embodiment of the present invention, the active layer 24 is formed to have the CQD structure, that is, the active layer 24 is formed with a plurality of quantum dot layers, which can be divided into three groups having different energy bands. Each group includes two quantum dot layers and each quantum dot layer is formed by alternatively forming a GaAs compound semiconductor layer (hereinafter referred as a GaAs layer) and an InAs compound semiconductor layer (hereinafter referred as a InAs layer) twice. In FIG. 5, each group is illustrated with one quantum dot layer 24e, 24f, 24g. Each quantum dot layer emits light of 1.2 μm 1.25 μm and 1.3 μm wavelengths when the electrons and holes are recombined. The lights having the desired wavelengths can be obtained by changing the physical and chemical characteristics of semiconductor layers that form the quantum dots. In this embodiment, the quantum dot layer 24e is obtained by forming an InAs layer. Before forming the quantum dot layer 24e, a GaAs layer 24b is formed on the first superlattice layer 23. At this time, the InAs layer is formed to a thickness of 0.8 nm in order to form the first quantum dot layer 24e emitting the light of 1.3 μm wavelength. The quantum layers 24f and 24g for 1.25 μm 1.2 μm wavelengths can be formed in the similar manner, but the thickness of the InAs layers should be varied to get the different wavelengths. For example, the InAs layer for forming the quantum layer 24f emitting the light of 1.25 μm wavelength is grown to a thickness of 0.75 nm, wherein the InAs layer for forming the quantum dot layer 24g emitting light of 1.2 μm wavelength is grown to a thickness of 0.7 nm. As mentioned above, three kinds of InAs layers for three different wavelengths are grown two layers by two layers. However, the number of kinds of the InAs layers can be more than three and the number of the InAs layers for each kind can be more than two. The quantum dot layers can be formed with an atomic layer epitaxy (ALE) instead of the S-K mode.

A second superlattice layer 25 is formed on the active layer 24 in the same manner of forming the first superlattice layer 23. Depending on the circumstances, the formation of first and second superlattice layers 23 and 24 can be omitted.

Subsequently, a p-type cladding layer 26 is formed on the second superlattice layer 25 by growing a Zn doped AlGaAs compound semiconductor layer. The p-type cladding layer 26 confines the lights emitted from the active layer 24 having the CQD structure with the n-type cladding layer 22.

A p+-type ohmic layer 27 is formed on the p-type cladding layer 26 by growing a Zn doped GaAs layer in order to control the ohmic contact of an electrode, which will be explained later.

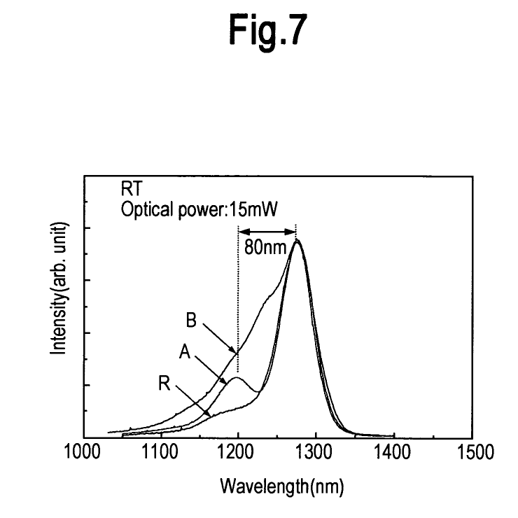

FIG. 7 is a graph showing photoluminescence (PL) characteristics of the CQD structures illustrated in FIGS. 4 and 5. Reference mark ‘A’ in FIG. 7 indicates the PL curve of the CQD structure of FIG. 4. In the PL curve A, two peaks centering around 1.3 μm and 1.2 μm are observed, as expected. The spacing between two peaks is approximately 80 nm. Reference mark ‘B’ in FIG. 7 is the PL curve of an active layer having the CQD structure shown in FIG. 5. In the PL curve B, a new peak corresponding to 1.25 μm is observed between the peaks around 1.3 μm and 1.2 μm. Due to this new peak, the full width at half maximum (FWHF) of the PL curve B increases. In FIG. 7, reference mark ‘R’ denotes the PL curve of an active layer having an epi-structure composed of the quantum dot layers for only 1.3 μm wavelength.

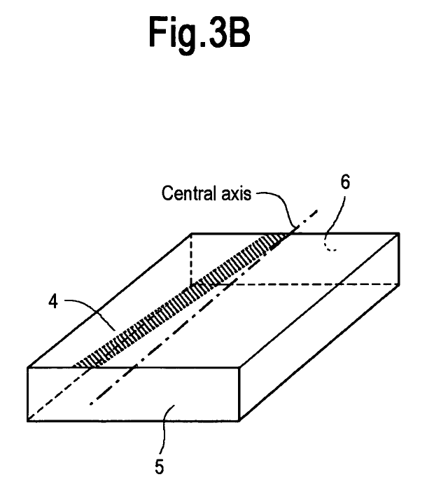

In the present invention, a J-shaped electrode, among the various electrodes shown in FIGS. 3A to 3C, is adopted to form superluminescent diodes having the active layer with CQD structures of FIGS. 4 and 5.

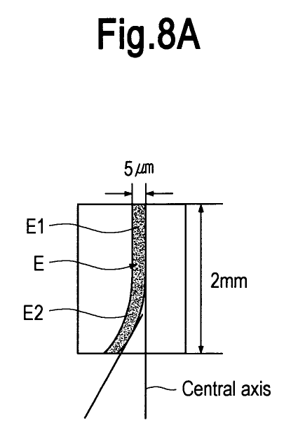

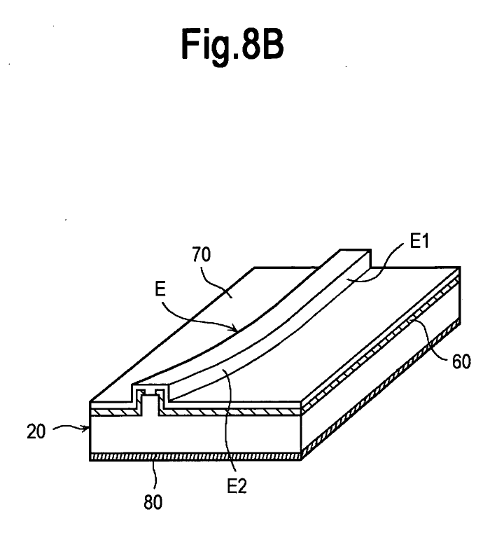

FIGS. 8A and 8B show a schematic structure of a superluminescent diode having the CQD structures in accordance with the first and second embodiments of the present invention. An electrode E having a J-shape is composed of a straight part E1 and a curved part E2. The curved part E2 slopes by approximately 6° against the central axis. The angle between the curved part E2 of the electrode and the central axis is determined in consideration of the wavelength, refractive index and width of the electrode. In the embodiment of the present invention, the width of the electrode is determined to be 5 μm so that the electrode can effectively combine with a single mode optical fiber.

Two mirrored-sides of the superluminescent diode having the epi-structure 20 illustrated in FIG. 6 are formed from both cleaved planes of the superluminescent diode. In addition, SiO₂ is deposited for forming an insulating layer 60 on the p+-type ohmic layer 27 shown in FIG. 6. Then, the insulation layer 60 is selectively etched to inject current into a J-shaped ridge. The length and width of the ridge are 2 mm and 5 μm, respectively, and the ridge slopes against the central axis by 6°. A metal layer 70, such as a Ti, a Pt and Au layers, etc, (hereinafter p-metal) is formed on the insulating layer 60, which is selectively opened. A thermal process is performed at a predetermined temperature to form an ohmic contact between the metal layer 70 and the ohmic layer 27. In FIG. 8B, the reference numeral ‘80’ denotes another metal layer formed on the back-side of the substrate (hereafter n-metal) which is lapped to predetermined thickness. The metal layer 80 is one of an AuGe layer, a Ni layer, and an Au layer, etc. When positive and negative voltages are applied to the p+-type ohmic layer 27 through p-metal and n+-type substrate 21 through n-metal, respectively, shown in FIG. 6, holes injected through the p+-type ohmic layer 27 and electrons injected through the n+-type substrate 21 move near the quantum dot in the active layer 24. The electrons and holes, which have moved to the quantum dots in the active layer, are recombined to emit light. The energy levels of the electrons and holes around the quantum dots having different sizes are different such as in the chirped quantum well (CQW) structure. As mentioned above, the quantum dots having the different sizes are formed with the InAs layers formed to the thickness 0.7 nm, 0.75 nm and 0.8 nm. Thus, lights of 1.2 μm, 1.25 μm and 1.3 μm wavelengths are emitted when the electrons and the holes are recombined. The lights of different wavelengths, which correspond to the different energy levels between the electrons and holes, are emitted to increase the wavelength bandwidth.

The light emitted from the quantum dot structure obtains optical gain due to the electrode E and the insulating layer 60 formed of SiO₂ when the light passes through a region of the active layer 24 located below the J-shaped electrode E. The optical gain cannot be obtained from the other regions of the active layer.

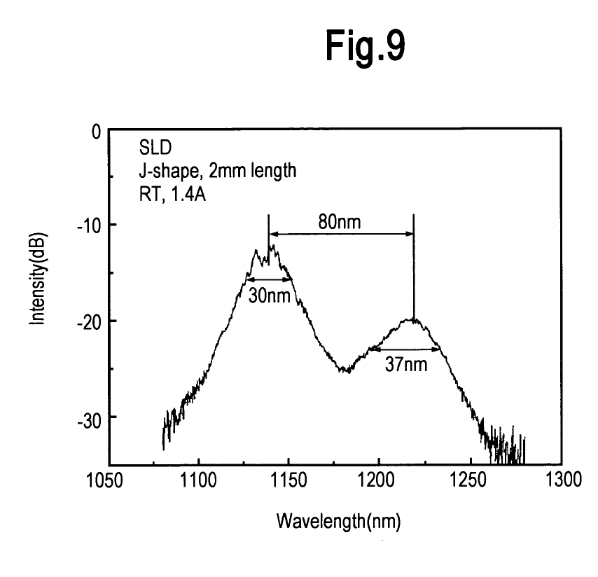

FIG. 9 shows electro-luminescence (EL) characteristics of superluminescent diode, which includes the active layer having the CQD structure of FIG. 4, and the J-shaped electrode. In FIG. 9, two peaks are observed and the spacing between the peaks is approximately 80 nm, which is exactly identical to the spacing between the two peaks in the PL curve A shown in FIG. 7. That is, it is observed that the PL characteristics of CQD are reflected on the EL characteristics. The bandwidths of two peaks are 30 nm and 37 nm, respectively. Thus, the total wavelength bandwidth of the superluminescent diode becomes 67 nm.

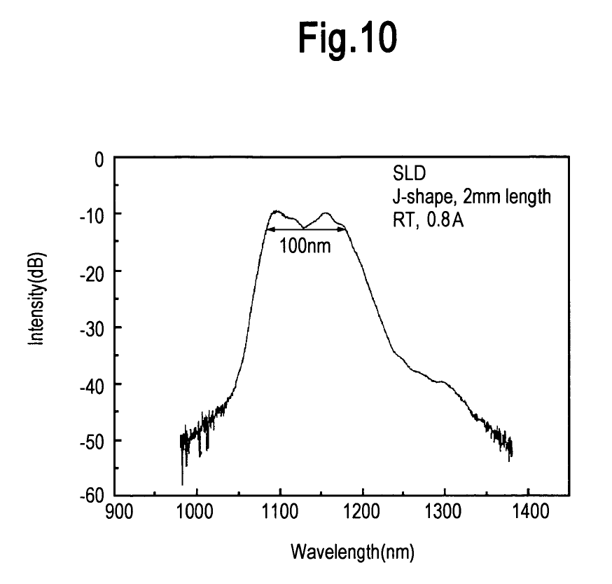

To form a superluminescent diode capable of emitting light with a wide wavelength bandwidth, a valley between the two peaks (shown in FIG. 9) should be lifted up. The valley can be lifted up by inserting an additional active layer capable of emitting light of a wavelength between the wavelengths of the two peaks. For example, the valley shown in FIG. 9 can be lifted up by forming the active layer, from which the light of 1.25 μm wavelength can be emitted (as shown in FIG. 5). FIG. 10 shows EL characteristics of the superluminescent diode, which includes the active layer having CQD structure in accordance with the second embodiment of the present invention. In view of such figure, it is certain that the valley between the two peaks can be filled up by forming the quantum dot layer emitting the light of 1.25 μm wavelength between the quantum dot layers emitting the light of 1.3 μm and 1.2 μm wavelengths, that is, a relatively flat wavelength bandwidth can be obtained. The flat wavelength bandwidth is approximately 100 nm.

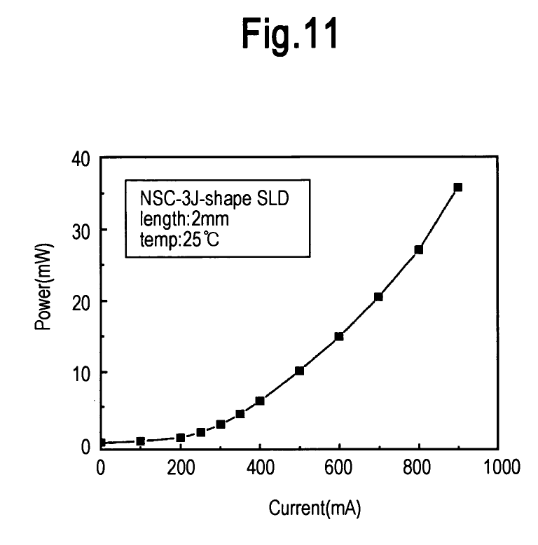

FIG. 11 shows the current-optical power characteristic of the superluminescent diode, which includes the active layer having the CQD structure of FIG. 5. The optical power starts increasing gradually when the current becomes 0.2 A. Also, the superluminescent diode outputs continuous optical power of 40 mW when the current is increased to 0.9 A.

With the superluminescent diode of the present invention, of which the active layer is formed with multi-layer quantum dots having various sizes (i.e., the CQD structure), the continuous optical power and wide wavelength bandwidth can be obtained. Further, the superluminescent diode of the present invention can play a role of a high brightness luminescent device in optical coherence tomography (OCT) and thus, the resolution image obtained from the OCT can be improved. In case of using the superluminescent diode of the present invention in wavelength division multiplexer-passive optical network (WDM-PON), the number of channels can be increased. Namely, the superluminescent diode of the present invention can replace the conventional expensive light source, i.e., a mode-locked Ti:Al₂O₃ laser in the OCT and tens of distributed feedback (DFB) lasers in the WDM-PON. Therefore, the manufacturing cost for OCT and WDM-PON system can be reduced.

It should be emphasized that although illustrative embodiments have been described herein in detail, that the description and drawings have been provided for purposes of illustration only and other variations, substitutions, and alterations, both in form and detail can be added thereupon without departing from the spirit and scope of the invention as set forth in the appended claims. The terms and expressions herein have been used as terms of description and not terms of limitation. There is no limitation to use the terms or expressions to exclude any equivalents of features shown and described or portions thereof. The scope of the invention should, therefore, be determined not with the reference to the above description, but should instead be determined with reference to the appended claims, along with the full scope of equivalents to which such claims are entitled.

What is claimed is:

1. A superluminescent diode, comprising:
a substrate;
an active layer having a chirped quantum dot (CQD) structure formed over the substrate, wherein the active layer emits lights of at least two different wavelengths;
a first cladding layer formed between the substrate and the active layer; and
a second cladding layer formed on the active layer, wherein the first and the second cladding layers confine the lights emitted from the active layer.

2. The superluminescent diode of claim 1, further comprising:
a first superlattice layer formed between the first cladding layer and the active layer; and
a second superlattice layer formed between the active layer and the second cladding layer.

3. The superluminescent diode of claim 2, further comprising:
an ohmic layer formed on the second cladding layer for controlling an ohmic contact; and
an electrode formed on the ohmic layer and having a shape for preventing a resonance mode from occurring.

4. The superluminescent diode of claim 1, wherein the active layer includes quantum dots grown by a Stranski-Krastinov (S-K) mode or an atomic layer epitaxy (ALE) mode.

5. The superluminescent diode of claim 1, wherein the wavelengths of lights can be changed by modifying the physical and chemical characteristics of semiconductor layers for forming the CQD structure.

6. A method of manufacturing a superluminescent diode, comprising the steps of:
providing a substrate;
forming a first cladding layer on the substrate;
forming an active layer having a chirped CQD structure on the first cladding layer, wherein the active layer emits lights of at least two different wavelengths; and
forming a second cladding layer on the active layer, wherein the second cladding layer confines the lights emitted from the active layer with the first cladding layer.

7. The method of manufacturing superluminescent diode of claim 6, further comprising the steps of:
forming a first superlattice layer on the first cladding layer prior to forming the active layer;
forming a second superlattice layer on the active layer prior to forming the second cladding layer.

8. The method of manufacturing superluminescent diode of claim 7, further comprising the steps of;
forming an ohmic layer for controlling an ohmic contact on the second cladding layer; and
forming an electrode having a shape for preventing a resonance mode from occurring on the ohmic layer.

9. The method of manufacturing superluminescent diode of claim 7, wherein the CQD structure of the active layer is grown by Stranski-Krastinov (S-K) mode or atomic layer epitaxy (ALE) mode.

10. The method of manufacturing superluminescent diode of claim 9, wherein the wavelengths of lights can be changed by modifying the physical and chemical characteristics of semiconductor layers for forming the CQD structure.
